(19) United States
(12) Patent Application Publication
(10) Pub. No.: US 2022/0285594 A1
(43) Pub. Date: Sep. 8, 2022

(54) LIGHT EMITTING DIODES WITH REFLECTIVE SIDEWALLS COMPRISING POROUS PARTICLES

(71) Applicant: LUMILEDS LLC, San Jose, CA (US)

(72) Inventors: Marcel Rene BOHMER, Eindhoven (NL); Kentaro SHIMIZU, Sunnyvale, CA (US)

(73) Assignee: Lumileds LLC, San Jose, CA (US)

(21) Appl. No.: 17/752,213

(22) Filed: May 24, 2022

Related U.S. Application Data
(63) Continuation of application No. PCT/US20/64318, filed on Dec. 10, 2020.
Application No. PCT/US20/64318 is a continuation-in-part of application No. 16/712,607, filed on Dec. 12, 2019, now Pat. No. 11,189,757.

(51) Int. Cl. H01L 33/60; H01L 33/52; H01L 27/15

(52) U.S. Cl. CPC H01L 33/60; H01L 33/52; H01L 27/156

(57) ABSTRACT

Sidewall reflectors disposed on the sidewalls of an LED or pcLED comprise porous (for example, hollow) high refractive index light scattering particles dispersed in a transparent binder. The porous particles exhibit a high refractive index contrast and corresponding strong scattering at the interfaces between the porous particle material and one or more pores in each particle. These sidewall reflectors can provide light confinement with thin reflector structures, allowing close spacing between LEDs and pcLEDs, and may be advantageously employed in microLED arrays.

### PRIORITY CLAIM

This application is a continuation of App No PCT/US2020/064318 entitled “Light emitting diodes with reflective sidewalls comprising porous particles” filed 10 Dec. 2020 in the names of Marcel Rene Bohmer and Kentaro Shimizu, which in turn claims priority of U.S. non-provisional application Ser. No. 16/712,607 entitled “Light emitting diodes with reflective sidewalls comprising porous particles” filed 12 Dec. 2019 in the names of Marcel Rene Bohmer and Kentaro Shimizu (now U.S. Pat. No. 11,189,757); both of said applications are incorporated by reference as if set forth herein in their entireties.

### FIELD OF THE INVENTION

The invention relates generally to phosphor-converted light emitting diodes.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer.

Phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED.

Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Multiple LEDs or pcLEDs can be formed together on a single substrate to form an array. Such arrays can be employed to form active illuminated displays, such as those employed in, e.g., smartphones and smart watches, computer or video displays, augmented- or virtual-reality displays, or signage, or to form adaptive illumination sources, such as those employed in, e.g., automotive headlights, camera flash sources, or flashlights (i.e., torches). An array having one or several or many individual devices per millimeter (e.g., device pitch of about a millimeter, a few hundred microns, or less than 100 microns, and spacing between adjacent devices less than 100 microns or only a few tens of microns or less) typically is referred to as a miniLED array or a microLED array (alternatively, a pLED array). Such mini- or microLED arrays can in many instances also include phosphor converters as described above; such arrays can be referred to as pc-miniLED or pc-microLED arrays.

### SUMMARY

An inventive light emitting device comprises a substrate, a semiconductor light emitting diode, a wavelength converting structure, and reflectors. The semiconductor light emitting diode is disposed on the substrate and includes a top surface, an oppositely positioned bottom surface adjacent the substrate, and sidewalls connecting the top and bottom surfaces. The wavelength converting structure comprises a top light output surface, an oppositely positioned bottom surface adjacent the top surface of the semiconductor light emitting diode, and side walls connecting the top and bottom surfaces. The reflectors are disposed on the sidewalls of the wavelength converting structure and the semiconductor light emitting diode, and comprise porous light scattering particles dispersed in a transparent binder. The porous light scattering particles each include therein one or more pores defined by inner surfaces of the porous light scattering particles.

Another inventive light emitting device comprises a plurality of phosphor converted light emitting diodes and a light scattering composition. The phosphor converted light emitting diodes are disposed on a shared substrate, with adjacent phosphor converted light emitting diodes separated by gaps. The light scattering composition fills the gaps to form sidewall reflectors shared by adjacent phosphor converted light emitting diodes. The light scattering composition comprises porous light scattering particles dispersed in a transparent binder. The porous light scattering particles each include therein one or more pores defined by inner surfaces of the porous light scattering particles.

Objects and advantages pertaining to LEDs, pcLEDs, miniLED arrays, pc-miniLED arrays, microLED arrays, and pc-microLED arrays may become apparent upon referring to the examples illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a schematic cross-sectional view of an example pcLED.

FIGS. 2A and 2B show, respectively, cross-sectional and top schematic views of an example array of pcLEDs. FIG. 2C shows a top schematic view of an example miniLED or microLED array and an enlarged section of 3x3 LEDs of the array. FIG. 2D shows a perspective view of several LEDs of an example pc-miniLED or pc-microLED array monolithically formed on a substrate.

FIG. 3A shows a schematic cross-sectional view of an example array of pcLEDs arranged with respect to waveguides and a projection lens. FIG. 3B shows an arrangement similar to that of FIG. 3A, but without the waveguides.

FIG. 4A shows a top schematic view of an example miniLED or microLED array and an enlarged section of 3×3 LEDs of the array. FIG. 4B shows a perspective view of several LEDs of an example pc-miniLED or pc-microLED array monolithically formed on a substrate. FIG. 4C is a side cross-sectional schematic diagram of an example of a close-packed array of multi-colored phosphor-converted LEDS on a monolithic die and substrate.

FIG. 5A is a schematic top view of a portion of an example LED display in which each display pixel is a red, green, or blue phosphor-converted LED pixel. FIG. 5B is a schematic top view of a portion of an example LED display in which each display pixel includes multiple phosphor-converted LED pixels (red, green, and blue) integrated onto a single die that is bonded to a control circuit backplane.

FIG. 6A shows a schematic top view an example electronics board on which an array of pcLEDs may be mounted, and FIG. 6B similarly shows an example array of pcLEDs mounted on the electronic board of FIG. 6A.

FIG. 7A, 7B, and 7C schematically illustrate an example process flow for forming a pcLED array comprising sidewall reflectors as described herein.

FIG. 8A schematically illustrates an example sidewall reflector comprising porous light scattering particles dispersed in a binder.

FIG. 8B schematically illustrates an example porous light scattering particle as may be employed in the sidewall reflector of FIG. 8A.

FIG. 8C schematically illustrates an example coated porous light scattering particle as may be employed in the sidewall reflector of FIG. 8B

The examples depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. For example, individual LEDs may be exaggerated in their vertical dimensions or layer thicknesses relative to their lateral extent or relative to substrate or phosphor thicknesses. The examples shown should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the invention. The detailed description illustrates by way of example, not by way of limitation, the principles of the invention.

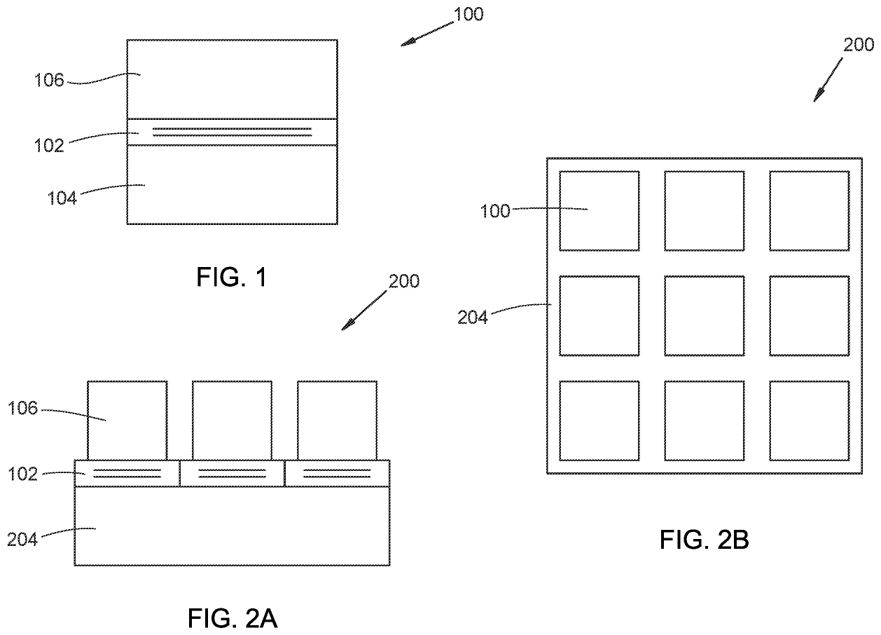

FIG. 1 shows an example of an individual pcLED 100 comprising a semiconductor diode structure 102 disposed on a substrate 104, together considered herein an “LED” or “semiconductor LED”, and a wavelength converting structure (e.g., phosphor layer) 106 disposed on the semiconductor LED. Semiconductor diode structure 102 typically comprises an active region disposed between n-type and p-type layers. Application of a suitable forward bias across the diode structure 102 results in emission of light from the active region. The wavelength of the emitted light is determined by the composition and structure of the active region.

The LED may be, for example, a III-Nitride LED that emits blue, violet, or ultraviolet light. LEDs formed from any other suitable material system and that emit any other suitable wavelength of light may also be used. Suitable material systems may include, for example, various III-Nitride materials, various III-Phosphide materials, various III-Arsenide materials, and various II-VI materials.

Any suitable phosphor materials may be used for or incorporated into the wavelength converting structure 106, depending on the desired optical output from the pcLED.

FIGS. 2A-2B show, respectively, cross-sectional and top views of an array 200 of pcLEDs 100, each including a phosphor pixel 106, disposed on a substrate 204. Such an array may include any suitable number of pcLEDs arranged in any suitable manner. In the illustrated example the array is depicted as formed monolithically on a shared substrate, but alternatively an array of pcLEDs may be formed from separate individual pcLEDs. Substrate 204 may optionally include electrical traces or interconnects, or CMOS or other circuitry for driving the LED, and may be formed from any suitable materials.

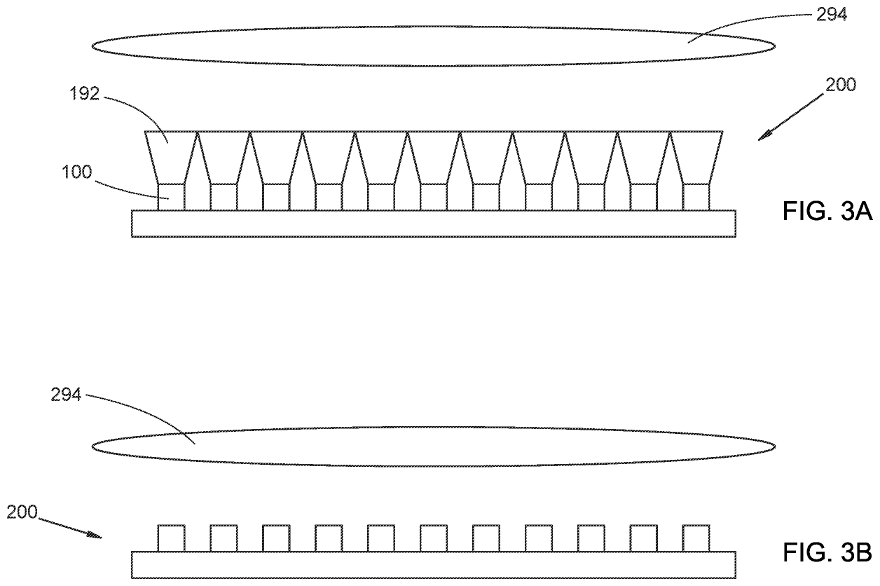

Individual pcLEDs 100 may optionally incorporate or be arranged in combination with a lens or other optical element located adjacent to or disposed on the phosphor layer. Such an optical element, not shown in the figures, may be referred to as a “primary optical element”. In addition, as shown in FIGS. 3A and 3B, a pcLED array 200 (for example, mounted on an electronics board) may be arranged in combination with secondary optical elements such as waveguides, lenses, or both for use in an intended application. In FIG. 3A, light emitted by each pcLED 100 of the array 200 is collected by a corresponding waveguide 192 and directed to a projection lens 294. Projection lens 294 may be a Fresnel lens, for example. This arrangement may be suitable for use, for example, in automobile headlights. In FIG. 3B, light emitted by pcLEDs of the array 200 is collected directly by projection lens 294 without use of intervening waveguides. This arrangement may particularly be suitable when pcLEDs can be spaced sufficiently close to each other, and may also be used in automobile headlights as well as in camera flash applications. A miniLED or microLED display application may use similar optical arrangements to those depicted in FIGS. 3A and 3B, for example. Generally, any suitable arrangement of optical elements may be used in combination with the pcLEDs described herein, depending on the desired application.

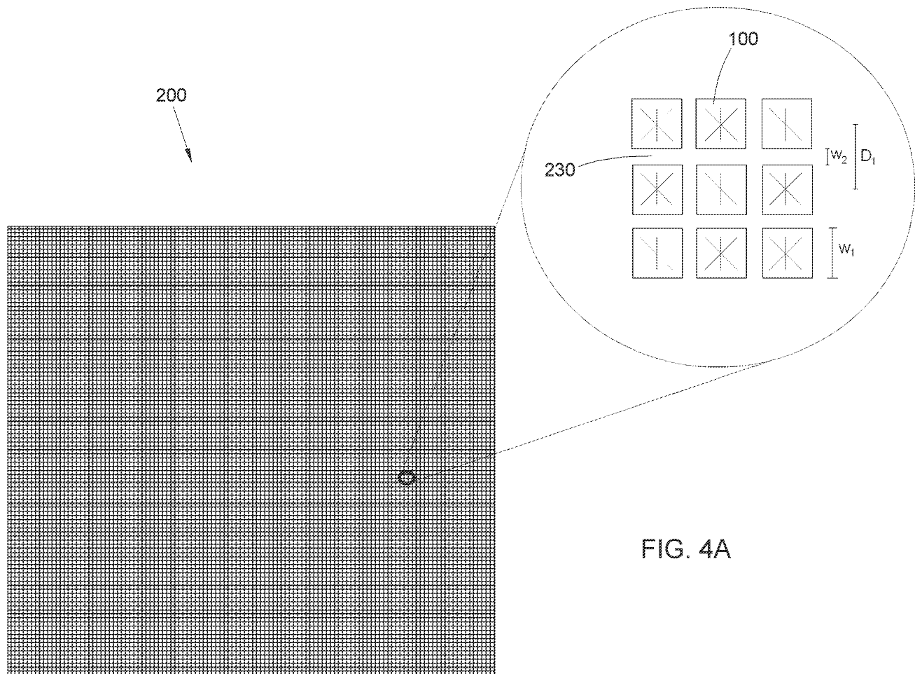

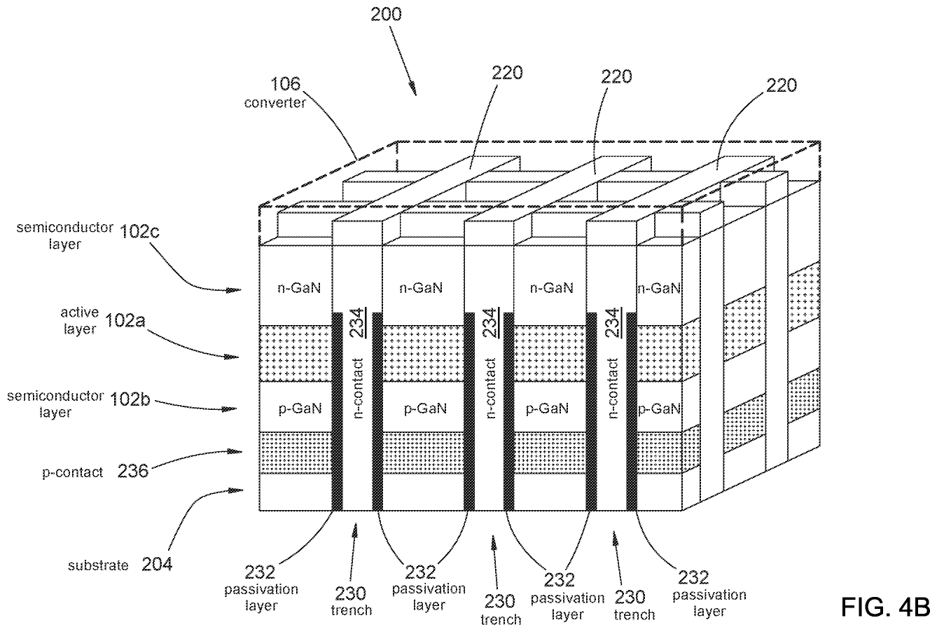

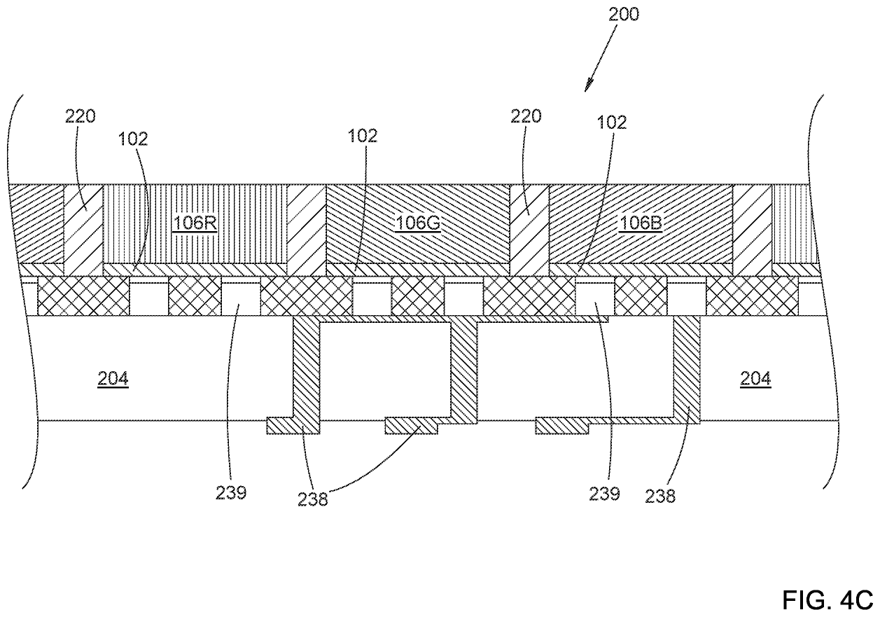

Although FIGS. 2A and 2B show a 3×3 array of nine pcLEDs, such arrays may include for example on the order of 10¹, 10², 10³, 10⁴, or more LEDs, e.g., as illustrated schematically in FIG. 4A. Individual LEDs 100 (i.e., pixels) may have widths wi (e.g., side lengths) in the plane of the array 200, for example, less than or equal to 1 millimeter (mm), less than or equal to 500 microns, less than or equal to 100 microns, or less than or equal to 50 microns. LEDs 100 in the array 200 may be spaced apart from each other by streets, lanes, or trenches 230 having a width w₂ in the plane of the array 200 of, for example, hundreds of microns, less than or equal to 100 microns, less than or equal to 50 microns, less than or equal to 20 microns, less than or equal to 10 microns, or less than or equal to 5 microns. The pixel pitch D₁ is the sum of w₁ and w₂. Although the illustrated examples show rectangular pixels arranged in a symmetric matrix, the pixels and the array may have any suitable shape or arrangement, whether symmetric or asymmetric. Multiple separate arrays of LEDs can be combined in any suitable arrangement in any applicable format to form a larger combined array or display.

LEDs having dimensions wi in the plane of the array (e.g., side lengths) of less than or equal to about 0.10 millimeters microns are typically referred to as microLEDs, and an array of such microLEDs may be referred to as a microLED array. LEDs having dimensions wi in the plane of the array (e.g., side lengths) of between about 0.10 millimeters and about 1.0 millimeters are typically referred to as miniLEDs, and an array of such miniLEDs may be referred to as a miniLED array.

An array of LEDs, miniLEDs, or microLEDs, or portions of such an array, may be formed as a segmented monolithic structure in which individual LED pixels are electrically isolated from each other by trenches and or insulating material. FIG. 4B shows a perspective view of an example of such a segmented monolithic LED array 200. Pixels in this array (i.e., individual semiconductor LED devices 102) are separated by trenches 230 which are filled to form n-contacts 234. The monolithic structure is grown or disposed on the substrate 204. Each pixel includes a p-contact 236, a p-GaN semiconductor layer 102b, an active region 102a, and an n-GaN semiconductor layer 102c; the layers 102a/102b/102c collectively form the semiconductor LED 102. A wavelength converter material 106 may be deposited on the semiconductor layer 102c (or other applicable intervening layer). Passivation layers 232 may be formed within the trenches 230 to separate at least a portion of the n-contacts 234 from one or more layers of the semiconductor. The n-contacts 234, other material within the trenches 230, or material different from material within the trenches 230 may extend into the converter material 106 to form complete or partial optical isolation barriers 220 between the pixels.

FIG. 4C is a schematic cross-sectional view of a close packed array 200 of multi-colored, phosphor converted LEDs 100 on a monolithic die and substrate 204. The side view shows GaN LEDs 102 attached to the substrate 204 through metal interconnects 239 (e.g., gold-gold interconnects or solder attached to copper micropillars) and metal interconnects 238. Phosphor pixels 106 are positioned on or over corresponding GaN LED pixels 102. The semiconductor LED pixels 102 or phosphor pixels 106 (often both) can be coated on their sides with a reflective mirror or diffusive scattering layer to form an optical isolation barrier 220. In this example each phosphor pixel 106 is one of three different colors, e.g., red phosphor pixels 106R, green phosphor pixels 106G, and blue phosphor pixels 106B (still referred to generally or collectively as phosphor pixels 106). Such an arrangement can enable use of the LED array 200 as a color display.

The individual LEDs (pixels) in an LED array may be individually addressable, may be addressable as part of a group or subset of the pixels in the array, or may not be addressable. Thus, light emitting pixel arrays are useful for any application requiring or benefiting from fine-grained intensity, spatial, and temporal control of light distribution. These applications may include, but are not limited to, precise special patterning of emitted light from pixel blocks or individual pixels, in some instances including the formation of images as a display device. Depending on the application, emitted light may be spectrally distinct, adaptive over time, and/or environmentally responsive. The light emitting pixel arrays may provide preprogrammed light distribution in various intensity, spatial, or temporal patterns. The emitted light may be based at least in part on received sensor data and may be used for optical wireless communications. Associated electronics and optics may be distinct at a pixel, pixel block, or device level.

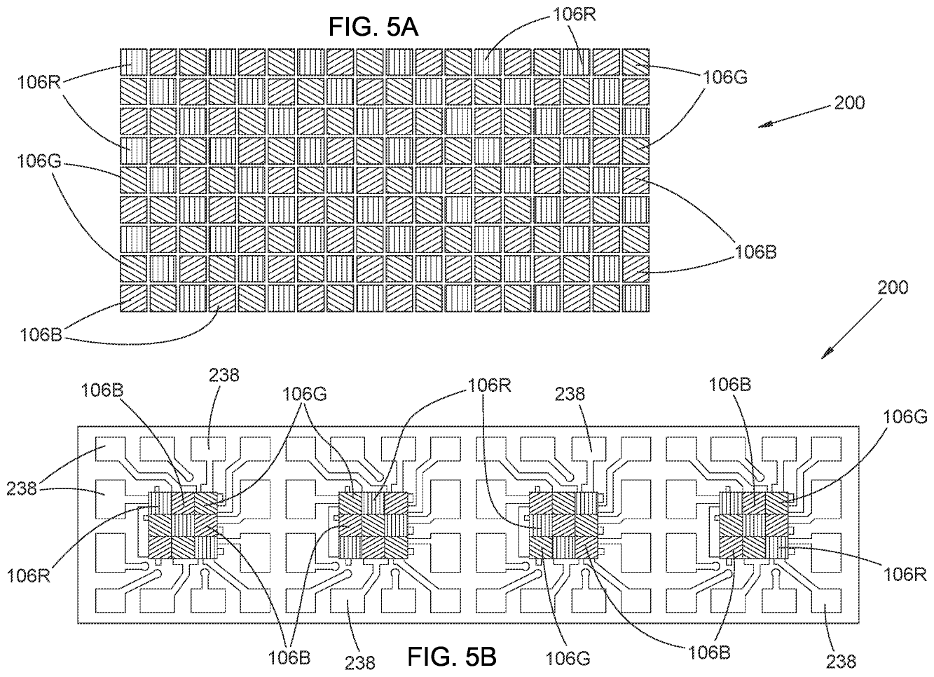

FIGS. 5A and 5B are examples of LED arrays 200 employed in display applications, wherein an LED display includes a multitude of display pixels. In some examples (e.g., as in FIG. 5A), each display pixel comprises a single semiconductor LED pixel 102 and a corresponding phosphor pixel 106R, 106G, or 106B of a single color (red, green, or blue). Each display pixel only provides one of the three colors. In some examples (e.g., as in FIG. 5B), each display pixel includes multiple semiconductor LED pixels 102 and multiple corresponding phosphor pixels 106 of multiple colors. In the example shown each display pixel includes a 3×3 array of semiconductor pixels 102; three of those LED pixels have red phosphor pixels 106R, three have green phosphor pixels 106G, and three have blue phosphor pixels 106B. Each display pixel can therefore produce any desired color combination. In the example shown the spatial arrangement of the different colored phosphor pixels 106 differs among the display pixels; in some examples (not shown) each display pixel can have the same arrangement of the different colored phosphor pixels 106.

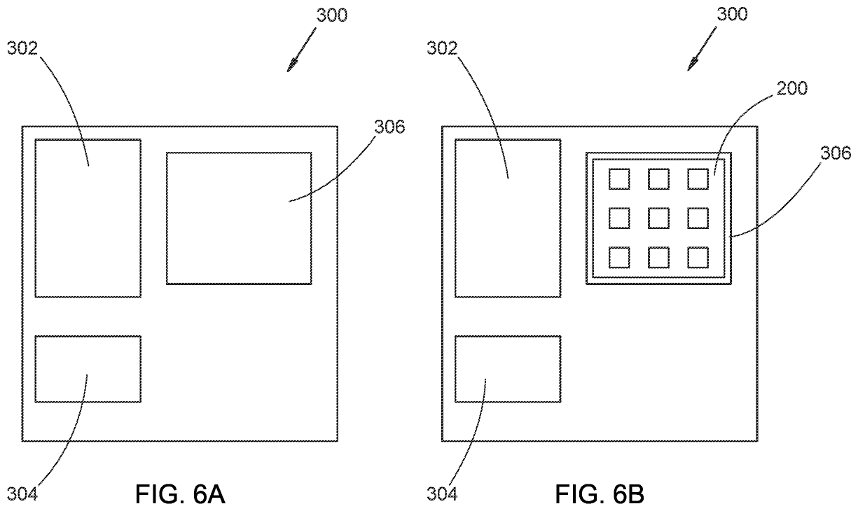

As shown in FIGS. 6A and 6B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

For many uses of pcLED arrays, it is desirable to compartmentalize the light emitted from the individual pcLEDs in the array. That is, it is advantageous to be able to operate an individual pcLED pixel in the array as a light source while adjacent pcLED pixels in the array remain dark. This allows for better control of displays or of illumination.

It is also advantageous in many applications to place the pcLEDs in an array close together. For example, a preferred configuration in microLEDs is to have minimal spacing between the individual LEDs. Also, closely spacing the pcLEDs in an array used as a camera flash light source or in an automobile headlight may simplify the requirements on any secondary optics and improve the illumination provided by the array.

However, if pcLEDs in an array are placed close together, optical cross talk between adjacent pcLED pixels may occur. That is, light emitted by a pcLED may scatter into or otherwise couple into an adjacent pcLED and appear to originate from that other pcLED, preventing the desired compartmentalization of light.

Conventionally, reflective sidewalls between adjacent pcLED pixels are used to reduce cross-talk. In one conventional approach, the reflective sidewalls are formed from high refractive index light scattering particles dispersed in a lower refractive index binder material. Light scattering arising from the high index contrast at the particle/binder interfaces optically isolates adjacent pixels from each other. Such conventional volume scattering approaches typically require a reflector sidewall thickness of greater than or equal to about 50 microns, for example, to provide sufficient optical isolation of adjacent pixels. The light scattering can be increased if the binder is replaced by air.

However, the mechanically stability of such a system is poor and it is prone to contamination.

In another conventional approach, reflective sidewalls are formed from specularly reflective metal layers or specularly reflective stacks of dielectric layers (e.g., distributed Bragg reflectors.

In some applications, it is desirable to space pcLED pixels with a separation of less than or equal to 50. microns, less than or equal to 20. microns, less than or equal to 10. microns, or less than or equal to 4 microns. In such applications, conventional volume scattering reflective structures as described above are thicker than desirable. Further, in such applications it is difficult to form specularly reflective sidewalls due to the high aspect ratios of the channels (gaps) between adjacent pixels.

As summarized above in the “summary” section, this specification discloses LEDs and pcLEDs having reflective sidewalls comprising porous (for example, hollow) high refractive index light scattering particles dispersed in a transparent binder material. The pores are filled with air or another gas, or are evacuated. Typically, the refractive index of the light scattering particle material is greater than or equal to about 2.0, or greater than or equal to about 2.5, the refractive index of the binder material is greater than or equal to about 1.4, and the refractive index of the (e.g., air-filled) pore is about 1.0. Light scattering in these sidewall reflectors arises mostly at the high refractive index contrast interfaces between the porous particle material and one or more voids in each particle, more than at the interface between the particle and the binder material. Because the refractive index of the pores is low (about 1.0) compared to 1.4 or more for the binder, more light scattering can be achieved with the same particle materials (in porous form) in the same binder. Alternatively, a porous particle material with a lower refractive index may be used to achieve the same amount of scattering as with conventional non-porous particle materials. Reflective sidewalls comprising such porous light scattering particles can provide desirable light confinement with thin reflector structures having, for example, a thickness of less than or equal to about 25 microns, less than or equal to about 15 microns, less than or equal to about 10. microns, or less than or equal to about 4 microns.

The porous light scattering particles may be, for example, porous Titanium

Oxide (TiO₂) particles or porous Zirconium Oxide (ZrO₂) particles, but other materials may be used if suitable. The particles may have diameters (or longest dimensions) of, for example, about 0.3 microns to about 10. microns. The pores (voids) in the particles may have diameters (or longest dimensions) of, for example, about 0.10 microns to about 0.50 microns, about 0.10 microns to about 0.25 microns, about 0.20 microns to about 0.25 microns, or about 0.30 microns. Pores having a diameter of about 0.20 microns to about 0.25 microns may provide maximum scattering. In some variations, porous light scattering particles have a diameter of about 0.30 microns and each include a single closed pore having a diameter of about 0.20 microns.

The size distribution of the light scattering particles may, for example, be bimodal with a first peak at a large diameter and a second peak at a diameter of at most about ¼ of the diameter of the first peak. This can be advantageous, with particles at the smaller of the two diameters fitting into gaps between particles of the larger of the two diameters.

Hollow particles, for instance hollow TiO2 particles, have been used to enhance the light harvesting in photovoltaic applications (Koh et al., advanced materials 2008; Yu, J. power sources 2011; Sasanpour, J. Opt. 2011). Most experiments and theoretical studies have concentrated on particles having a single pore, but for use in sidewall reflectors as described herein it may be advantageous to form larger particles with a plurality of pores, as long as the particle size is significantly smaller than the spacing between pcLEDs. Apart from spherical particles, cylindrical hollow particles can be used to enhance the scattering effect (Sasanpour et al.).

The porous particles may include open pores, closed pores, or both open and closed pores. Open pores have a connection to the outer surface of the particle, and thus for example to the binder.

Porous particles comprising open pores may be coated with a hydrophobic material that prevents binder material from flowing into and filling or partially filling the open pores during the deposition and curing processes by which the sidewall reflectors are formed. The hydrophobic coating may coat internal surfaces defining the open pores, for example. Porous particles not comprising open pores may also be coated with a hydrophobic material to reduce sensitivity to moisture. Suitable hydrophobic materials may include, for example, silanes having hydrophobic (e.g., organic) side groups such as, for example, alkoxy-alkylsilanes, chloro-alkylsilanes, hexamethyldisilazane, and fluorinated silanes.

The transparent binder material may be for example a silicone or a sol-gel glass material.

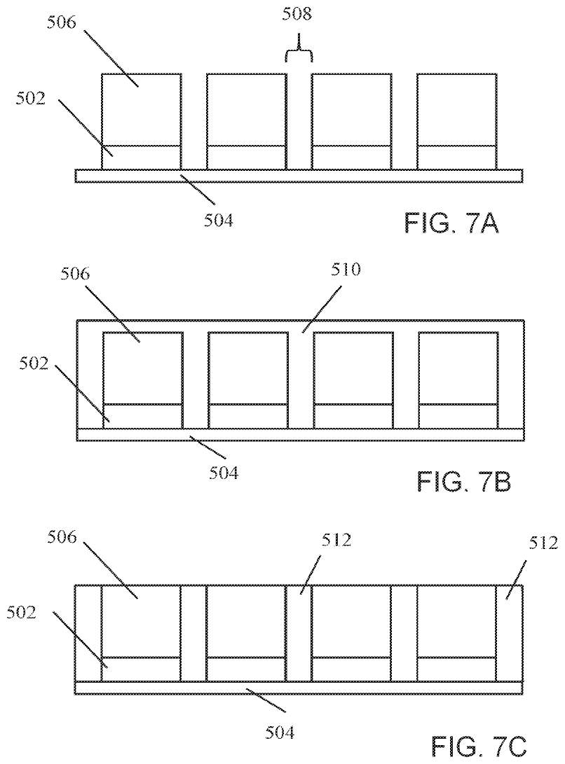

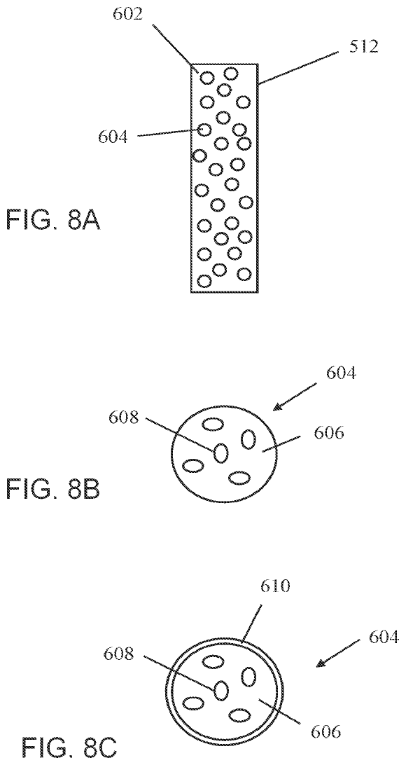

An example process flow for making a pcLED array employing such sidewall reflectors is described next with respect to FIGS. 7A-7C. Any other suitable process may be used instead. Details of the example sidewall reflectors are described with respect to FIGS. 8A-8C.

FIG. 7A schematically illustrates in a cross-sectional view a portion of an example pcLED array. In the array, semiconductor light emitting diodes 502 are mounted on a substrate 504. A wavelength converting structure 506 is located on an upper surface of each light emitting diode 502, opposite from substrate 504, to form a pcLED. The wavelength converting structures 506 may be ceramic phosphor structures, phosphor particles dispersed in a binder, or any other suitable wavelength converting structure. Adjacent pcLED pixels are separated from each other by a street (gap) having a width 508. Width 508 may be, for example, less than or equal to about 50. microns, less than or equal to about 20. microns, or less than or equal to about 10. microns, but any suitable spacing may be used.

As shown in FIG. 7B a layer 510 of a light scattering composition comprising porous light scattering particles dispersed in a binder, as described above, is disposed in the streets between the pcLEDs in contact with sidewalls of the pcLEDs, and optionally over top surfaces of the pcLEDs. Layer 510 may be deposited by, for example, spin coating, spray coating, over-molding, printing, or any other suitable deposition method.

As shown in FIG. 7C, any light scattering composition present on top surfaces of the pcLEDs is removed and the remaining light scattering composition is cured to form reflective sidewalls 512 extending from substrate 504 to top light emitting surfaces of the wavelength converting structures 506.

FIG. 8A schematically shows detail of an example reflective sidewall reflector 512 comprising porous light scattering particles 604 dispersed in a binder 602. FIG. 8B schematically shows details of an example porous light scattering particle 604, comprising one or more voids 608 in particle material 606. FIG. 8C schematically shows the porous light scattering particle of FIG. 8B coated with a hydrophobic coating 610 preventing binder material 602 from entering pores 608 during deposition and curing of the light scattering composition. Hydrophobic coating 610 may, for example, penetrate or partially penetrate voids 608 that open to a surface of particle 604. Coating 610 need not form a continuous physical barrier layer as schematically shown in FIG. 8C.

In addition to the preceding, the following example embodiments fall within the scope of the present disclosure or appended claims:

Example 1. A light emitting device comprising: a substrate; a semiconductor light emitting diode disposed on the substrate, the semiconductor diode comprising a top surface, an oppositely positioned bottom surface adjacent the substrate, and sidewalls connecting the top and bottom surfaces; a wavelength converting structure comprising a top light output surface, an oppositely positioned bottom surface adjacent the top surface of the semiconductor light emitting diode, and side walls connecting the top and bottom surfaces; and reflectors disposed on the sidewalls of the wavelength converting structure and the semiconductor light emitting diode, the reflectors comprising porous light scattering particles dispersed in a transparent binder, the porous light scattering particles each including therein one or more pores defined by inner surfaces of the porous light scattering particles.

Example 2. The light emitting device of Example 1, wherein at least some of the porous light scattering particles include therein one or more gas-filled pores.

Example 3. The light emitting device of any one of Examples 1 or 2, wherein at least some of the porous light scattering particles include therein one or more evacuated pores.

Example 4. The light emitting device of any one of Examples 1 through 3, wherein at least some of the porous light scattering particles include therein one or more closed pores.

Example 5. The light emitting device of any one of Examples 1 through 4, wherein at least some of the porous light scattering particles include therein one or more open pores.

Example 6. The light emitting device of any one of Examples 1 through 5, wherein the porous light scattering particles have a refractive index of greater than or equal to about 2.0 and the pores have a refractive index of about 1.0.

Example 7. The light emitting device of any one of Examples 1 through 6, wherein the porous light scattering particles have transverse sizes of about 0.3 microns to about 10. microns.

Example 8. The light emitting device of any one of Examples 1 through 7, wherein the porous light scattering particles have a bimodal size distribution with a first peak at a first transverse size and a second peak at about one fourth or less of the first transverse size.

Example 9. The light emitting device of any one of Examples 1 through 8, wherein the pores have transverse sizes of about 0.10 microns to about 0.50 microns.

Example 10. The light emitting device of any one of Examples 1 through 9, wherein at least some of the porous light scattering particles include a hydrophobic coating.

Example 11. The light emitting device of Example 10, wherein the hydrophobic coating coats internal surfaces of at least some of the pores in the porous light scattering particles.

Example 12. The light emitting device of any one of Examples 1 through 11, wherein: the porous light scattering particles have a refractive index of greater than or equal to about 2.0; the pores have a refractive index of about 1.0; and at least some of the porous light scattering particles include a hydrophobic coating.

Example 13. The light emitting device of Example 12, wherein the porous light scattering particles have diameters of about 0.3 microns to about 10. microns.

Example 14. The light emitting device of any one of Examples 12 or 13, wherein the pores have transverse sizes of about 0.20 microns to about 0.25 microns.

Example 15. A light emitting device comprising: a plurality of phosphor converted light emitting diodes disposed on a shared substrate with adjacent phosphor converted light emitting diodes separated by gaps; and a light scattering composition filling the gaps to form sidewall reflectors shared by adjacent phosphor converted light emitting diodes, the light scattering composition comprising porous light scattering particles dispersed in a transparent binder, the porous light scattering particles each including one or more pores defined by inner surfaces of the porous light scattering particles.

Example 16. The light emitting device of Example 15, wherein at least some of the porous light scattering particles include therein one or more gas-filled pores.

Example 17. The light emitting device of any one of Examples 15 or 16, wherein at least some of the porous light scattering particles include therein one or more evacuated pores.

Example 18. The light emitting device of any one of Examples 15 through 17, wherein at least some of the porous light scattering particles include therein one or more closed pores.

Example 19. The light emitting device of any one of Examples 15 through 18, wherein at least some of the porous light scattering particles include therein one or more open pores.

Example 20. The light emitting device of any one of Examples 15 through 19, wherein the gaps have a width between adjacent phosphor converted light emitting diodes of less than or equal to about 50 microns.

Example 21. The light emitting device of Example 20, wherein the gaps have a width between adjacent phosphor converted light emitting diodes of less than or equal to about 15 microns.

Example 22. The light emitting device of any one of Examples 15 through 21, wherein the porous light scattering particles have a refractive index of greater than or equal to about 2.0 and the pores have a refractive index of about 1.0.

Example 23. The light emitting device of any one of Examples 15 through 22, wherein the porous light scattering particles have transverse sizes of about 0.3 microns to about 10. microns.

Example 24. The light emitting device of any one of Examples 15 through 23, wherein the pores have transverse sizes of about 0.10 microns to about 0.50 microns.

Example 25. The light emitting device of any one of Examples 15 through 24, wherein one or more of the porous light scattering particles include a hydrophobic coating.

Example 26. The light emitting device of Example 25, wherein the hydrophobic coating coats internal surfaces of at least some of the pores in the porous particle.

Example 27. The light emitting device of any one of Examples 15 through 26, wherein: the gaps have a width between adjacent phosphor converted light emitting diodes of less than or equal to about 50 microns; the porous light scattering particles have a refractive index of greater than or equal to about 2.0 and diameters of about 0.3 microns to about 10. microns; the pores have diameters of about 0.10 microns to about 0.50 microns and a refractive index of about 1.0; and the porous light scattering particles each comprise a hydrophobic coating.

Example 28. The light emitting device of Example 27, wherein the gaps have a width between adjacent phosphor converted light emitting diodes of less than or equal to about 15 microns.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed example embodiment. Therefore, the present disclosure shall be construed as implicitly disclosing any embodiment having any suitable subset of one or more features — which features are shown, described, or claimed in the present application — including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each. In another example, each of “a dog, a cat, or a mouse,” “one or more of a dog, a cat, or a mouse,” and “one or more dogs, cats, or mice” would be interpreted as (i) one or more dogs without any cats or mice, (ii) one or more cats without and dogs or mice, (iii) one or more mice without any dogs or cats, (iv) one or more dogs and one or more cats without any mice, (v) one or more dogs and one or more mice without any cats, (vi) one or more cats and one or more mice without any dogs, or (vii) one or more dogs, one or more cats, and one or more mice. In another example, each of “two or more of a dog, a cat, or a mouse” or “two or more dogs, cats, or mice” would be interpreted as (i) one or more dogs and one or more cats without any mice, (ii) one or more dogs and one or more mice without any cats, (iii) one or more cats and one or more mice without and dogs, or (iv) one or more dogs, one or more cats, and one or more mice; “three or more,” “four or more,” and so on would be analogously interpreted.

For purposes of the present disclosure or appended claims, when terms are employed such as “about equal to,” “substantially equal to,” “greater than about,” “less than about,” and so forth, in relation to a numerical quantity, standard conventions pertaining to measurement precision and significant digits shall apply, unless a differing interpretation is explicitly set forth. For null quantities described by phrases such as “substantially prevented,” “substantially absent,” “substantially eliminated,” “about equal to zero,” “negligible,” and so forth, each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled.

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112(f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112(f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A light emitting device comprising:
a substrate;
a semiconductor light emitting diode disposed on the substrate, the semiconductor diode comprising a top surface, an oppositely positioned bottom surface adjacent the substrate, and sidewalls connecting the top and bottom surfaces of the semiconductor diode, the semiconductor diode having non-zero transverse dimensions less than about 1.0 mm;
a wavelength converting structure comprising a top light output surface, an oppositely positioned bottom surface adjacent the top surface of the semiconductor light emitting diode, and side walls connecting the top and bottom surfaces of the wavelength converting structure; and
reflectors disposed on only the sidewalls of the wavelength converting structure and on only the sidewalls of the semiconductor light emitting diode, the reflectors comprising porous light scattering particles dispersed in a transparent binder, the porous light scattering particles each including therein one or more pores defined by inner surfaces of the porous light scattering particles, the reflectors substantially preventing transmission of light exiting the light emitting device through the side walls of the semiconductor diode or through the side walls of the wavelength converting structure.

2. The light emitting device of claim 1, the semiconductor diode having non-zero transverse dimensions less than about 0.2 mm.

3. The light emitting device of claim 1, wherein (i) at least some of the porous light scattering particles include therein one or more gas-filled pores, or (ii) at least some of the porous light scattering particles include therein one or more evacuated pores.

4. The light emitting device of claim 1, wherein at least some of the porous light scattering particles include therein one or more closed pores.

5. The light emitting device of claim 1, wherein at least some of the porous light scattering particles include therein one or more open pores.

6. The light emitting device of claim 1, wherein the porous light scattering particles have a refractive index of greater than or equal to about 2.0 and the pores have a refractive index of about 1.0.

7. The light emitting device of claim 1, wherein (i) the porous light scattering particles have transverse sizes of about 0.3 microns to about 10. microns, or (ii) the pores have transverse sizes of about 0.10 microns to about 0.5 microns.

8. The light emitting device of claim 1, wherein the porous light scattering particles have a bimodal size distribution with a first peak at a first transverse size and a second peak at about one fourth or less of the first transverse size.

9. The light emitting device of claim 1, wherein at least some of the porous light scattering particles include a hydrophobic coating.

10. The light emitting device of claim 9, wherein the hydrophobic coating coats internal surfaces of at least some of the pores in the porous light scattering particles.

11. A light emitting device comprising:
a plurality of phosphor converted light emitting diodes disposed on a shared substrate with adjacent pairs of the phosphor converted light emitting diodes separated by corresponding gaps, each phosphor converted light emitting diode having non-zero transverse dimensions less than about 1.0 mm, each gap having a non-zero width less than about 0.1 mm; and
a light scattering composition filling only the gaps to form corresponding sidewall reflectors shared by corresponding adjacent pairs of the phosphor converted light emitting diodes, the light scattering composition comprising porous light scattering particles dispersed in a transparent binder, the porous light scattering particles each including one or more pores defined by inner surfaces of the porous light scattering particles, the sidewall reflectors substantially preventing transmission of light across the gaps between the corresponding adjacent pairs of the phosphor converted light emitting diodes.

12. The light emitting device of claim 11, wherein (i) each phosphor converted light emitting diode has non-zero transverse dimensions less than about 0.2 mm, or (ii) each gap has a non-zero width less than about 0.05 mm.

13. The light emitting device of claim 11, wherein (i) each phosphor converted light emitting diode has non-zero transverse dimensions less than about 0.10 mm, or (ii) each gap has a non-zero width less than about 0.015 mm.

14. The light emitting device of claim 11, wherein (i) at least some of the porous light scattering particles include therein one or more gas-filled pores, or (ii) at least some of the porous light scattering particles include therein one or more evacuated pores.

15. The light emitting device of claim 11, wherein at least some of the porous light scattering particles include therein one or more closed pores.

16. The light emitting device of claim 11, wherein at least some of the porous light scattering particles include therein one or more open pores.

17. The light emitting device of claim 11, wherein the porous light scattering particles have a refractive index of greater than or equal to about 2.0 and the pores have a refractive index of about 1.0.

18. The light emitting device of claim 11, wherein (i) the porous light scattering particles have transverse sizes of about 0.3 microns to about 10. microns, or (ii) the pores have transverse sizes of about 0.10 microns to about 0.50 microns.

19. The light emitting device of claim 11, wherein at least some of the porous light scattering particles include a hydrophobic coating.

20. The light emitting device of claim 19, wherein the hydrophobic coating coats internal surfaces of at least some of the pores in the porous particle.
